(19) United States
(12) Patent Application Publication
(10) Pub. No.: US 2025/0222533 A1
(43) Pub. Date: Jul. 10, 2025

(54) BONDED STRUCTURE, METHOD FOR PRODUCING SAME, CONDUCTIVE MEMBER FOR SOLDER BONDING, AND STRUCTURE FOR SOLDER BONDING

(71) Applicant: Murata Manufacturing Co., Ltd., Nagaokakyo-shi (JP)

(72) Inventors: Yasunori HIOKI, Nagaokakyo-shi (JP); Kazuari SASAKI, Nagaokakyo-shi (JP); Mayuko NISHIHARA, Nagaokakyo-shi (JP)

(21) Appl. No.: 19/089,465

(22) Filed: Mar. 25, 2025

Related U.S. Application Data
(63) Continuation of application No. PCT/JP2023/033022, filed on Sep. 11, 2023.

(30) Foreign Application Priority Data
Sep. 29, 2022 (JP) 2022-156859

(51) Int. Cl. B23K 1/00; B22F 3/02; B22F 3/14; B23K 35/26; B23K 101/42; H05K 3/34

(52) U.S. Cl. CPC B23K 1/0016; B22F 3/02; B22F 3/14; B23K 35/262; H05K 3/3463; B22F 2201/11; B22F 2301/255; B22F 2998/10; B23K 2101/42

(57) ABSTRACT

A bonded structure that includes: a first conductive member; a second conductive member; and a solder-bonded part for bonding the first conductive member and the second conductive member, wherein at least one of the first conductive member and the second conductive member includes a metal and particles including one or more layers.

### CROSS REFERENCE TO RELATED APPLICATIONS

The present application is a continuation of International application No. PCT/JP2023/033022, filed Sep. 11, 2023, which claims priority to Japanese Patent Application No. 2022-156859, filed Sep. 29, 2022, the entire contents of each of which are incorporated herein by reference.

### TECHNICAL FIELD

The present disclosure relates to a bonded structure, a method for producing the bonded structure, a conductive member for solder bonding, and a structure for solder bonding.

### BACKGROUND ART

Generally, an electronic component includes a component body and an external electrode provided on a surface of the component body, and when the electronic component is mounted on a substrate, the external electrode can be solder-bonded to an electrode part (for example, a land) formed on the substrate (In the present specification, a bonded part formed by this is also referred to as a “solder-bonded part”.). In solder bonding, so-called “dissolution of metallization during soldering” may occur in which metal constituting an external electrode excessively diffuses due to contact with a solder material. As a measure to prevent this “dissolution of metallization during soldering”, for example, a step of forming a barrier layer such as nickel plating on the surface of the wiring or the electrode can be mentioned. However, the pretreatment with a chemical solution such as an acid or an alkali causes a decrease in adhesion strength of the conductor to the substrate, and causes a problem of high cost due to addition of a plating process.

For example, when the metal constituting the external electrode is particularly silver, it is possible to use a silver/palladium conductor or a silver/platinum conductor to which palladium or platinum having high heat resistance is added. In addition, examples of a technique for forming surface layer wiring by a post-fire by a thick film method include a conductive paste in which an oxide of manganese, chromium oxide, and glass frit are added to silver/palladium. However, the post-fire by the thick film method increases the number of steps, and thus the cost increases.

In addition, the glass frit is softened during firing and accumulated between the conductor particles. Therefore, when dissolution of metallization during soldering occurs on the conductor surface, a layer formed of the remaining glass is exposed, and there is a problem that the solder material is repelled. Furthermore, since the silver/palladium conductor has high conductor resistance, there is a problem that conductor loss of an electric signal in the surface layer wiring is large.

As another countermeasure, Patent Document 1 discloses a conductive paste including 0.2 to 1 parts by weight of manganese dioxide, 0.2 to 1 parts by weight of copper oxide, 0.3 to 1 parts by weight of silicon dioxide, and 3 to 5.6 parts by weight of metal powders of molybdenum and tungsten with respect to 100 parts by weight of silver/platinum.
Patent Document 1: JP-A-2001-143527

### SUMMARY OF THE DISCLOSURE

For example, an electrode or wiring constituting an electronic component is required to exhibit high conductivity while preventing dissolution of metallization during soldering. However, the structure disclosed in Patent Document 1 also has a problem that the number of man-hours increases and the cost increases. The present disclosure has been made in view of the above circumstances, and an object of the present disclosure is to provide a bonded structure that prevents dissolution of metallization during soldering and is excellent in conductivity, a method for producing the bonded structure at low cost, a conductive member for solder bonding, and a structure for solder bonding.

According to one gist of the present disclosure, there is provided a bonded structure including: a first conductive member; a second conductive member; and a solder-bonded part that bonds the first conductive member and the second conductive member, wherein at least one of the first conductive member and the second conductive member includes a metal and particles including one or more layers.

As a bonded structure according to a preferred aspect of the present disclosure, there is provided a bonded structure including: a first conductive member; a second conductive member; and a solder-bonded part that bonds the first conductive member and the second conductive member, wherein at least one of the first conductive member and the second conductive member includes:
a metal; and
one or more conductive particles of
(i) first conductive particles being particles of a layered material including one or more layers, the layer including a layer body represented by the following formula:

MₘXₙ
where, M is at least one Group 3, 4, 5, 6, or 7 metal,
X is a carbon atom, a nitrogen atom, or a combination thereof,
n is not less than 1 and not more than 4, and
m is greater than n and 5 or less; and
a modification or termination T (T is at least one selected from the group consisting of a hydroxyl group, a fluorine atom, a chlorine atom, an oxygen atom, and a hydrogen atom.) present on a surface of the layer body; and
(ii) second conductive particles represented by the following formula:

MₘAXₙ
where, M is at least one Group 3, 4, 5, 6, or 7 metal,
X is a carbon atom, a nitrogen atom, or a combination thereof,
A is at least one group 12, 13, 14, 15, or 16 element,
n is not less than 1 and not more than 4, and
m is greater than n and 5 or less.

According to the present disclosure, there is provided a bonded structure including: a first conductive member; a second conductive member; and a solder-bonded part that bonds the first conductive member and the second conductive member, in which at least one of the first conductive member and the second conductive member includes a metal and particles of a layered material including one or more layers, preferably one or more conductive particles of a predetermined first conductive particles and a predetermined second conductive particles, dissolution of metallization during soldering is prevented, and high conductivity is exhibited.

### BRIEF DESCRIPTION OF THE DRAWINGS

FIG. 1 is a schematic cross-sectional view showing a part of a conventional bonded structure.

FIG. 2 is a schematic cross-sectional view showing a part of the bonded structure according to the present embodiment.

FIGS. 3(a) and 3(b) are schematic cross-sectional views showing MXene which is a layered material usable for the bonded structure according to the present embodiment.

FIG. 4 is a schematic cross-sectional view of a mounting structure in which an electronic component is mounted on a substrate, which is illustrated as an example of the bonded structure according to the present embodiment.

FIG. 5 is a graph showing the relationship between the immersion time in the solder bath and the mass of the conductive member sample, which is the result of the dissolution of metallization during soldering test in Examples.

FIG. 6 is a microphotograph showing an appearance of a sample before and after a dissolution of metallization during soldering test in Examples.

### DETAILED DESCRIPTION

### Embodiment 1: Bonded Structure

Hereinafter, a bonded structure according to an embodiment of the present disclosure is described in detail, and the present disclosure is not limited to such an embodiment.

One bonded structure according to the present embodiment is a bonded structure including: a first conductive member; a second conductive member; and a solder-bonded part that bonds the first conductive member and the second conductive member, wherein at least one of the first conductive member and the second conductive member includes a metal and particles of a layered material including one or more layers.

Examples of the particles of a layered material including one or more layers in the bonded structure include MXene particles to be described in detail later, MAX particles to be described in detail later, graphene, graphene oxide, silicene, black phosphorus, borophene, titanium oxide nanosheets, transition metal dichalcogenides, boron nitride, and the like, and include including one or more particles thereof. Since at least one of the first conductive member and the second conductive member includes particles of a layered material including one or more layers, dissolution of metallization during soldering can be prevented even if the metal is silver, copper, or the like that easily diffuses into solder metal (for example, tin or the like) at the time of solder bonding. The particles of a layered material including one or more layers in the bonded structure preferably include one or more particles of MXene particles and MAX particles and/or one or more particles of graphene and graphene oxide. The particles of a layered material including one or more layers in the bonded structure may be one or more particles of MXene particles and MAX particles. The particles of a layered material including one or more layers in the bonded structure may be one or more particles of graphene and graphene oxide. The particles of a layered material including one or more layers in the bonded structure are more preferably particles of a layered material including one or more layers, and the layer is one or more of MXene represented by the following formula:

MₘXₙ

and MAX represented by the following formula:

MₘAXₙ.

A preferred bonded structure according to the present embodiment includes: a bonded structure including: a first conductive member; a second conductive member; and a solder-bonded part that bonds the first conductive member and the second conductive member, wherein at least one of the first conductive member and the second conductive member includes:
a metal; and
one or more conductive particles of
(i) first conductive particles being particles of a layered material including one or more layers, the layer including a layer body represented by the following formula:

MₘXₙ
where, M is at least one Group 3, 4, 5, 6, or 7 metal,
X is a carbon atom, a nitrogen atom, or a combination thereof,
n is not less than 1 and not more than 4, and
m is greater than n and 5 or less; and
a modification or termination T (T is at least one selected from the group consisting of a hydroxyl group, a fluorine atom, a chlorine atom, an oxygen atom, and a hydrogen atom.) present on a surface of the layer body; and
(ii) second conductive particles represented by the following formula:

MₘAXₙ
where, M is at least one Group 3, 4, 5, 6, or 7 metal,
X is a carbon atom, a nitrogen atom, or a combination thereof,
A is at least one group 12, 13, 14, 15, or 16 element,
n is not less than 1 and not more than 4, and
m is greater than n and 5 or less. Hereinafter, this preferred bonded structure is described in detail.

### [Conductive Member]

[One or more conductive particles of the first conductive particles (MXene particles) and the second conductive particles (MAX particles) included in the conductive member]

In the bonded structure according to the present embodiment, at least one of the first conductive member and the second conductive member may include one or more conductive particles of the first conductive particles and the second conductive particles together with metal. In the present specification, the first conductive particles may be referred to as “MXene particles” or “MXene powder”, and the layered material constituting the first conductive particles may be referred to as “MXene”. The second conductive particles may be referred to as “MAX particles”, and the layered material constituting the second conductive particles may be referred to as “MAX”.

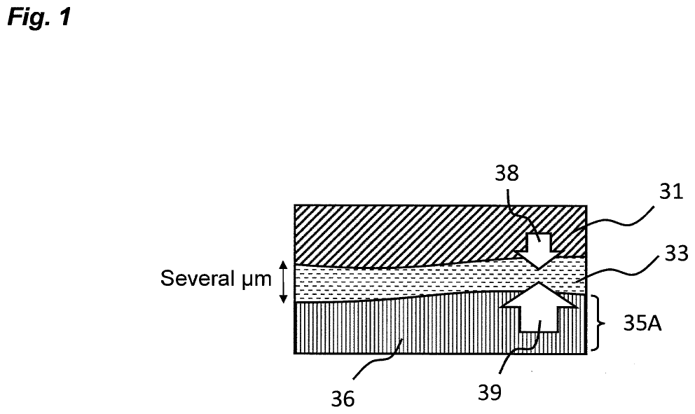

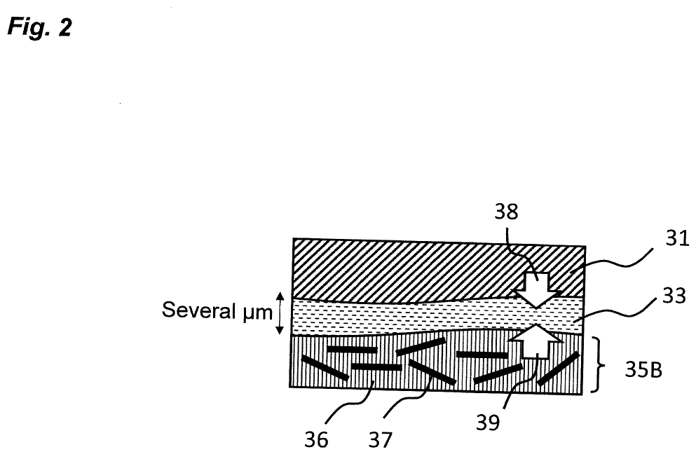

With the above configuration, the bonded structure according to the present embodiment can prevent dissolution of metallization during soldering even when the metal is silver, copper, or the like that easily diffuses into a solder metal (for example, tin or the like) at the time of solder bonding. Although the present embodiment is not bound by any theory, the reason why the bonded structure according to the present embodiment can prevent dissolution of metallization during soldering is presumed as follows using the schematic cross-sectional views of FIGS. 1 and 2. Note that FIGS. 1 and 2 are image diagrams used for convenience of description, and the thickness of the solder-bonded part, the size, arrangement, and the like of one or more conductive particles of MXene particles and MAX particles in FIGS. 1 and 2 may be different from the actual ones, and the bonded structure according to the present embodiment is not limited to the embodiment illustrated in FIG. 2.

FIG. 1 is a schematic cross-sectional view showing a part of a conventional bonded structure, and FIG. 2 is a schematic cross-sectional view showing a part of a bonded structure according to the present embodiment.

For solder bonding, when heating is performed in a state where a metal such as silver or copper constituting a conductive member and a solder metal such as tin included in the solder material are in contact with each other, an alloy layer (intermetallic compound) of these metals is formed as a solder-bonded part by diffusion of the metal constituting the conductive member and diffusion of the solder metal. By forming the alloy layer (intermetallic compound), the strength of the bonded structure can be secured, and conductivity can also be secured. However, when the metal constituting the conductive member is likely to diffuse into the solder metal like silver, for example, as shown in FIG. 1, diffusion (diffusion into the solder metal (tin or the like) 39 of the metal 36 such as silver constituting the conductive member 35A becomes excessive. As a result, most of the metal 36 such as silver constituting the conductive member 35A is used for forming the alloy layer (intermetallic compound) 33, and the conductive member 35A disappears, so-called “dissolution of metallization during soldering” occurs.

However, as shown in FIG. 2, it is considered that the conductive member 35B contains the metal 36 and one or more conductive particles 37 of the first conductive particles (MXene particles) and the second conductive particles (MAX particles), thereby inhibiting the diffusion 39 of the metal 36 such as silver constituting the conductive member 35B. As a result, it is considered that excessive diffusion into the solder metal is suppressed, and dissolution of metallization during soldering can be prevented. As shown in Examples described later, among particles of a layered material including one or more layers, one or more conductive particles of conductive particles (MXene particles) and second conductive particles (MAX particles) can prevent dissolution of metallization during soldering and exhibit high conductivity.

Hereinafter, each of the first conductive particles and the second conductive particles is described.

The layered material constituting the first conductive particles may be understood as a layered compound and is also referred to as “MₘXₙTₛ”, s is any number, and x or z may be conventionally used instead of s. Typically, n can be 1, 2, 3, or 4, but is not limited thereto.

In the above formula of MXene, M is preferably at least one selected from the group consisting of Ti, Zr, Hf, V, Nb, Ta, Cr, Mo, and Mn, and more preferably at least one selected from the group consisting of Ti, V, Cr, and Mo.

MXene whose above formula

MₘXₙ

is expressed as below are known:
Sc₂C, Ti₂C, Ti₂N, Zr₂C, Zr₂N, Hf₂C, Hf₂N, V₂C, V₂N, Nb₂C, Ta₂C, Cr₂C, Cr₂N, Mo₂C, Mo_{1.3}C, Cr_{1.3}C, (Ti,V)₂C, (Ti,Nb)₂C, W₂C, W_{1.3}C, Mo₂N, Nb_{1.3}C, Mo_{1.3}Y_{0.6}C (wherein “1.3” and “0.6” mean about 1.3 (=4/3) and about 0.6 (=2/3), respectively),
Ti₃C₂, Ti₃N₂, Ti₃(CN), Zr₃C₂, (Ti,V)₃C₂, (Ti₂Nb)C₂, (Ti₂Ta)C₂, (Ti₂Mn)C₂, Hf₃C₂, (Hf₂V)C₂, (Hf₂Mn)C₂, (V₂Ti)C₂, (Cr₂Ti)C₂, (Cr₂V)C₂, (Cr₂Nb)C₂, (Cr₂Ta)C₂, (Mo₂Sc)C₂, (Mo₂Ti)C₂, (Mo₂Zr)C₂, (Mo₂Hf)C₂, (Mo₂V)C₂, (Mo₂Nb)C₂, (Mo₂Ta)C₂, (W₂Ti)C₂, (W₂Zr)C₂, (W₂Hf)C₂,
Ti₄N₃, V₄C₃, Nb₄C₃, Ta₄C₃, (Ti,Nb)₄C₃, (Nb,Zr)₄C₃, (Ti₂Nb₂)C₃, (Ti₂Ta₂)C₃, (V₂Ti₂)C₃, (V₂Nb₂)C₃, (V₂Ta₂)C₃, (Nb₂Ta₂)C₃, (Cr₂Ti₂)C₃, (Cr₂V₂)C₃, (Cr₂Nb₂)C₃, (Cr₂Ta₂)C₃, (Mo₂Ti₂)C₃, (Mo₂Zr₂)C₃, (Mo₂Hf₂)C₃, (Mo₂V₂)C₃, (Mo₂Nb₂)C₃, (Mo₂Ta₂)C₃, (W₂Ti₂)C₃, (W₂Zr₂)C₃, and (W₂Hf₂)C₃,(Mo_{2.7}V_{1.3})C₃, (wherein “2.7” and “1.3” mean about 2.7 (=8/3) and about 1.3 (=4/3), respectively.)

Typically in the above formula, M can be titanium or vanadium and X can be a carbon atom or a nitrogen atom. For example, the MAX phase is Ti₃AlC₂ and MXene is Ti₃C₂Tₛ (in other words, M is Ti, X is C, n is 2, and m is 3).

It is noted, in the present disclosure, MXene may contain remaining A atoms at a relatively small amount, for example, at 10% by mass or less with respect to the original amount of A atoms. The remaining amount of A atoms can be preferably 8% by mass or less, and more preferably 6% by mass or less. However, even if the residual amount of A atoms exceeds 10% by mass, there may be no problem depending on the application and use conditions of the conductive member.

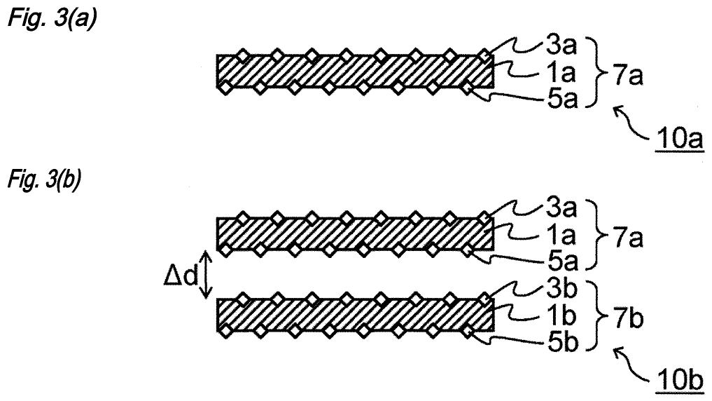

The MXene particle is an aggregate including one layer of MXene 10a (single-layer MXene) schematically exemplified in FIG. 3. More specifically, the MXene 10a is an MXene layer 7a having a layer body (MₘXₙ layer) la represented by MₘXₙ and modifications or terminations T 3a, 5a present on the surface of the layer body 1a (more specifically, at least one of two surfaces facing each other in each layer). Therefore, the MXene layer 7a is also represented as “MₘXₙTₛ”, and s is an arbitrary number.

The MXene particle may contain a plurality of layers of MXene together with one layer of MXene. Examples of the MXene (multilayer MXene) of the plurality of layers include, and are not limited to, two layers of MXene10b as schematically illustrated in FIG. 3(b). 1b, 3b, 5b, and 7b in FIG. 3(b) are the same as 1a, 3a, 5a, and 7a in FIG. 3(a) described above. Two adjacent MXene layers (for example, 7a and 7b) of the multilayer MXene may not necessarily be completely separated from each other, but may be partially in contact with each other. The MXene 10a may be a mixture of the single-layer MXene 10a and the multilayer MXene10b in which the multilayer MXene10b is individually separated and presents as one layer and the unseparated multilayer MXene10b remains.

Although the present embodiment is not limited, the thickness of each layer (corresponds to the MXene layers 7a and 7b) in the MXene particles is, for example, 0.8 nm to 5 nm, particularly 0.8 nm to 3 nm (and may vary mainly depending on the number of M atom layers included in each layer.). For each laminate of multilayer MXene particles that may be contained, the interlayer distance (alternatively, the void dimension is indicated by Ad in FIG. 3(b)) may be, for example, 0.8 nm to 10 nm, particularly 0.8 nm to 5 nm, and more particularly about 1 nm, and the total number of layers may be 2 to 20,000.

The MXene particles may be MXene with few layers obtained by subjecting the multilayer MXene to an interlayer peeling treatment (also referred to as a delamination treatment). The “few layers” means that, for example, the number of laminated layers of MXene is six or less. In addition, the thickness of the multilayer MXene with few layers in the lamination direction can be 10 nm or less. Hereinafter, the “multilayer MXene with few layers” may be referred to as a “few-layer MXene”. In addition, the single-layer MXene and the few-layer MXene may be collectively referred to as “single-layer/few-layer MXene”.

The MXene particle may contain a single-layer MXene and a few-layer MXene, that is, a single-layer/few-layer MXene. The proportion of the single-layer/few-layer MXene having a thickness of 10 nm or less to the entire MXene particles can be 10 vol % or more when the MXene particles are used for a resin-free conductive member, and can be 1 vol % or more when the MXene particles are used for a resin-including conductive member. When used for any of the conductive members, the proportion of the single-layer/few-layer MXene may be higher.

The proportion of one or more conductive particles (Hereinafter, referred to as “MXene particles/MAX particles” or simply “conductive particles”.) of MXene particles and MAX particles contained in at least one of the first conductive member and the second conductive member may be, for example, in the following range. That is, when the proportion of the conductive particles is represented by (mass of conductive particles)/(mass of conductive particles+mass of metal constituting conductive member), the proportion can be, for example, 0.1% by mass to 20% by mass. However, the present disclosure is not limited thereto, and the proportion of the conductive particles may be more than 20% by mass. On the other hand, the proportion of the conductive particles is preferably 20% by mass or less from the viewpoint of forming an intermetallic compound between the metal included in conductive member and the solder and performing good solder bonding.

### [Metal Included in Conductive Member]

The metal contained in at least one of the first conductive member and the second conductive member is at least one selected from the group consisting of silver, copper, gold, nickel, zinc, tin, platinum, and palladium. These metals are easily diffused into solder metals constituting the solder material, such as tin, and dissolution of metallization during soldering easily occurs when these metals are solder bonded as an object to be bonded. The metal may be each pure metal or an alloy including 50% or more of each pure metal by mass. The metal may in particular be one or more of silver and copper, and in particular may be silver. At least one of the first conductive member and the second conductive member includes, for example, 80% by mass or more of the metal.

### [Solder-Bonded Part]

The solder-bonded part refers to a bonded part formed between the first conductive member and the second conductive member so as to be in contact with the first conductive member and the second conductive member by solder bonding the first conductive member and the second conductive member via a solder material including solder metal.

### [Solder Metal Included in Solder-Bonded Part]

The “solder metal” means a metal for brazing. Examples of the solder metal include a lead-free solder metal. The solder metal may contain at least tin. Examples of the solder metal including tin (Sn) include Sn alone or a Sn-based alloy. Examples of the Sn—based alloy include Sn—Cu, Sn—Ag, Sn—Ag—Cu, Sn—In, Sn—Ag—In, Sn—Cu—In, Sn—Ag—Cu—In, Sn—Bi, Sn—Bi—In, Sn—Ag—Bi, Sn—Cu—Bi, Sn—Ag—Cu—Bi, Sn—Ag—Cu—Bi—In, Sn—Au, Sn—Sb, and Sn—Zn.

### [Resin Included in Solder-Bonded Part]

The solder-bonded part may contain a resin depending on a raw material for solder bonding and bonding conditions. The resin contained in the solder-bonded part is not limited, and may be a thermosetting resin or a thermoplastic resin. Examples thereof include acrylic resins, fluororesins such as polytetrafluoroethylene, vinyl resins such as polyvinyl chloride, epoxy resins, polyurethane, melamine resins, phenol resins, polyesters such as polyethylene terephthalate, polyamides, polyimides, and polyethers. The proportion of the resin contained in the solder-bonded part may be appropriately determined according to the application.

### Embodiment of Bonded Structure

The bonded structure according to the present embodiment is obtained by solder bonding the first conductive member and the second conductive member. Examples of at least one of the first conductive member and the second conductive member include an electrode and a wiring. Examples of the “electrode” include an internal electrode, an external electrode, a pad electrode, a wiring electrode, a ground (reference potential) electrode, and a shield pattern in an electronic component or a circuit board, which may cause the dissolution of metallization during soldering. Examples of the “wiring” include a signal line forming a circuit pattern, a coil pattern, and an interlayer connection conductor (via conductor).

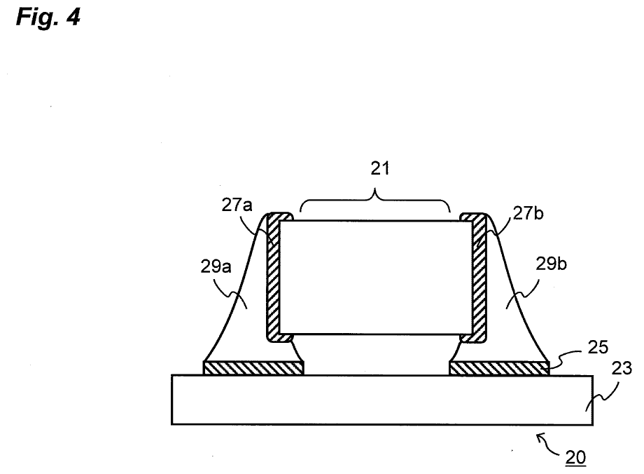

As an example of the bonded structure, FIG. 4 shows a schematic cross-sectional view of a mounting structure obtained by mounting an electronic component on a substrate using a solder material. In FIG. 4, a mounting structure 20 includes an electronic component and solder-bonded parts 29a, 29b. In the mounting structure 20, the electronic component includes a component body 21 and external electrodes 27a and 27b provided on the surface of the component body. In FIG. 4, two external electrodes are shown as the external electrodes, and the number of external electrodes is not particularly limited. The solder-bonded parts 29a and 29b bond the substrate 23 and the electronic component, and specifically, may be directly bonded to an electrode part 25 provided on the surface of the substrate 23.

### Embodiment 2: Method for Producing Bonded Structure

Hereinafter, a method for producing a bonded structure according to an embodiment of the present disclosure is described in detail, but the present disclosure is not limited to such an embodiment.

A method for producing a bonded structure according to the present embodiment, the method including:
(a) preparing a first conductive member and a second conductive member, wherein at least one of the first conductive member and the second conductive member includes:
a metal; and
one or more conductive particles of
(i) first conductive particles being particles of a layered material including one or more layers, the layer including a layer body represented by the following formula:

MₘXₙ
where, M is at least one Group 3, 4, 5, 6, or 7 metal,
X is a carbon atom, a nitrogen atom, or a combination thereof,
n is not less than 1 and not more than 4, and
m is greater than n and 5 or less; and
a modification or termination T (T is at least one selected from the group consisting of a hydroxyl group, a fluorine atom, a chlorine atom, an oxygen atom, and a hydrogen atom.) present on a surface of the layer body, and
(ii) second conductive particles represented by the following formula:

MₘAXₙ
where, M is at least one Group 3, 4, 5, 6, or 7 metal,
X is a carbon atom, a nitrogen atom, or a combination thereof,
A is at least one group 12, 13, 14, 15, or 16 element,
n is not less than 1 and not more than 4, and
m is greater than n and 5 or less; and
(b) solder bonding the first conductive member and the second conductive member.
Each step is described below.

### Step (a)

A first conductive member and a second conductive member, wherein at least one of the first conductive member and the second conductive member includes a metal, and one or more conductive particles of (i) the first conductive particles and (ii) the second conductive particles, is prepared.

As a method of preparing at least one conductive member of a first conductive member and a second conductive member including the metal and the conductive particles in the above (a), the following method can be mentioned.

In the step (a), at least one of the first conductive member and the second conductive member may be prepared by a step including:
(a11) preparing one or more conductive particles of
(i) first conductive particles being particles of a layered material including one or more layers, the layer including a layer body represented by the following formula:

MₘXₙ
where, M is at least one Group 3, 4, 5, 6, or 7 metal,
X is a carbon atom, a nitrogen atom, or a combination thereof,
n is not less than 1 and not more than 4, and
m is greater than n and 5 or less; and
a modification or termination T (T is at least one selected from the group consisting of a hydroxyl group, a fluorine atom, a chlorine atom, an oxygen atom, and a hydrogen atom.) present on a surface of the layer body, and
(ii) second conductive particles represented by the following formula:

MₘAXₙ
where, M is at least one Group 3, 4, 5, 6, or 7 metal,
X is a carbon atom, a nitrogen atom, or a combination thereof,
A is at least one group 12, 13, 14, 15, or 16 element,
n is not less than 1 and not more than 4, and
m is greater than n and 5 or less;
(a12) obtaining a mixture for forming a conductive member by mixing a composition for forming a conductive member including a metal constituting at least one of the first conductive member and the second conductive member and the conductive particles; and
(a13) molding the mixture for forming a conductive member and firing the mixture at a sinterable temperature (This may be referred to as the “first step (a)”).

Another method for preparing the conductive member includes the following method.

In the step (a), at least one of the first conductive member and the second conductive member may be prepared by a step including:
(a21) preparing one or more conductive particles of
(i) first conductive particles being particles of a layered material including one or more layers, the layer including a layer body represented by the following formula:

MₘXₙ
where, M is at least one Group 3, 4, 5, 6, or 7 metal,
X is a carbon atom, a nitrogen atom, or a combination thereof,
n is not less than 1 and not more than 4, and
m is greater than n and 5 or less; and
a modification or termination T (T is at least one selected from the group consisting of a hydroxyl group, a fluorine atom, a chlorine atom, an oxygen atom, and a hydrogen atom.) present on a surface of the layer body, and
(ii) second conductive particles represented by the following formula:

MₘAXₙ
where, M is at least one Group 3, 4, 5, 6, or 7 metal,
X is a carbon atom, a nitrogen atom, or a combination thereof,
A is at least one group 12, 13, 14, 15, or 16 element,
n is not less than 1 and not more than 4, and
m is greater than n and 5 or less;
(a22) obtaining a mixture for forming a conductive member by mixing a composition for forming a conductive member including a metal constituting at least one of the first conductive member and the second conductive member and the conductive particles, and a resin; and
(a23) molding and drying the mixture for forming a conductive member (also referred to as the “second step (a)”).

Hereinafter, the first step (a) is described.

Step (a11)

The first conductive particles and the second conductive particles can be prepared as follows.

First, MAX constituting the second conductive particles is represented by the following formula below:

MₘAXₙ
where M, X, n, and m are as described above, A is at least one element of Group 12, 13, 14, 15, or 16, normally an element of Group A, typically of Group IIIA and Group IVA, more specifically can include at least one selected from the group consisting of Al, Ga, In, Tl, Si, Ge, Sn, Pb, P, As, S, and Cd, and is preferably Al; and
has a crystal structure in which a layer composed of A atoms is located between the two layers represented by MₘXₙ (may have a crystal lattice in which each X is located in the octahedral array of M). When typically m=n+1, but not limited thereto, the MAX phase includes repeating units in which each one layer of X atoms is disposed in between adjacent layers of n+1 layers of M atoms (these are also collectively referred to as an “MₘXₙ layer”), and a layer of A atoms (“A atom layer”) is disposed as a layer next to the (n+1)th layer of M atoms.

The MAX phase can be produced by a known method. For example, a TiC powder, a Ti powder, and an Al powder are mixed in a ball mill, and the resulting mixed powder is fired under an Ar atmosphere to obtain a fired body (block-shaped MAX phase). Thereafter, the obtained fired body can be pulverized with an end mill to obtain MAX particles.

The first conductive particles (MXene particles) can be synthesized by selectively etching (removing and optionally layer-separating) A atoms (and optionally part of M atoms) from the MAX.

By selectively etching (removing and optionally layer-separating) A atoms (and optionally part of M atoms) from MAX, the A atomic layer (and optionally part of M atoms) is removed, and a hydroxyl group, a fluorine atom, a chlorine atom, an oxygen atom, a hydrogen atom, and the like present in the etching liquid (usually, an aqueous solution of a fluorine-containing acid is used, but not limited thereto) are modified on the exposed surface of the MₘXₙ layer, thereby the surface is terminated.

The etching can be carried out using an etching liquid containing F⁻, and a method using, for example, a mixed liquid of lithium fluoride and hydrochloric acid, a method using hydrofluoric acid, or the like may be used. The etching liquid includes a metal compound including a monovalent metal ion, and the intercalation treatment of a monovalent metal ion may be performed simultaneously with the etching.

After the etching, layer separation (delamination, separating multilayer MXene into single-layer MXene) of MXene may be promoted by any appropriate post-treatment (For example, ultrasonic treatment, handshaking, automatic shaker, or the like) as appropriate. For example, an intercalation treatment of monovalent metal ions may be performed including a step of mixing the etching product obtained by the etching treatment with a metal compound including monovalent metal ions. Since the shear force of an ultrasonic treatment is too large so that the MXene can be destroyed, it is desirable to apply an appropriate shear force by handshake, an automatic shaker or the like, when it is desired to obtain a two-dimensional MXene (preferably single-layer MXene) having a larger aspect ratio.

Step (a12)

A composition for forming a conductive member including a metal constituting at least one of the first conductive member and the second conductive member and the conductive particles is mixed to obtain a mixture for forming a conductive member. The metal is as described above in [Metal included in conductive member]. The metal may be, for example, a metal powder. A metal paste including the metal powder may be used. Examples of the metal paste include a metal paste obtained by mixing an Ag powder with a varnish prepared by mixing conductive particles, a solvent, and a resin (organic component). When a metal paste including a resin is used as described above, the composition for forming a conductive member may contain a resin. The mixing method is not particularly limited, and examples thereof include stirring with a centrifugal stirrer, kneading using a three-roll mill, and dispersion treatment. In the kneading, when the fluidity is reduced, an organic solvent that can be removed in the subsequent drying step, for example, diethylene glycol monobutyl ether acetate used in Examples, may be added.

Step (a13)

The mixture for forming a conductive member is molded and fired at a sinterable temperature to obtain a conductive member including conductive particles.

The molding method is not particularly limited, and for example, the molding may be performed by applying the mixture to an object to be applied such as a substrate. The coating method is not limited, and examples thereof include a method of performing spray coating using a nozzle such as a one-fluid nozzle, a two-fluid nozzle, or an air brush, and a coating method by slit coating using a table coater, a comma coater, or a bar coater, screen printing, metal mask printing, spin coating, dip coating, dropping, or the like. The object to be applied may be appropriately employed as a printed circuit board, a metal substrate, a resin substrate, a laminated electronic component, a metal pin, a metal wire, or the like depending on the application. The mixture may be molded, for example, dried to obtain a molded product, and then fired. When drying is performed after molding, the drying is performed, depending on the shape and size of the molded product, for example, in a range of 60° C. to 200° C. for 10 minutes to 120 minutes. As shown in Examples described later, molding and firing may be performed simultaneously.

The molded product is fired at a sinterable temperature. The sinterable temperature may be determined depending on the metal species within a range of, for example, approximately 150° C. to 1450° C. The firing time may be determined according to the shape and size of the molded product. The atmosphere during firing is not particularly limited. For the purpose of removing the binder and the like, the atmosphere during firing can be appropriately adjusted to an inert atmosphere, an oxidizing atmosphere, or a reducing atmosphere.

Next, the second step (a) is described. Parts overlapping with the first step (a) are omitted.

Step (a21)

The first conductive particles and the second conductive particles can be prepared in the same manner as in the step (a11).

Step (a22)

A composition for forming a conductive member including a metal constituting at least one of the first conductive member and the second conductive member, the conductive particles, and a resin is mixed to obtain a mixture for forming a conductive member.

The metal is as described in the above step (a12) [Metal included in conductive member].

The resin is not limited, and the resin described above in [Resin included in solder-bonded part] can be used. That is, it may be a thermosetting resin or a thermoplastic resin. Examples thereof include acrylic resins, fluororesins such as polytetrafluoroethylene, vinyl resins such as polyvinyl chloride, epoxy resins, polyurethane, melamine resins, phenol resins, polyesters such as polyethylene terephthalate, polyamides, polyimides, and polyethers. The proportion of the resin is, for example, more than 0% by mass, preferably 2% by mass or more in order to exhibit a function as a binder, and on the other hand, is preferably 25% by mass or less, and more preferably 12% by mass or less from the viewpoint of ensuring conductivity.

As the metal and the resin, a metal paste in which these are mixed in advance can be used. The proportion of the conductive particles contained in the composition for forming a conductive member may be adjusted so that the proportion of the conductive particles of the resulting conductive member falls within the range of 0.1% by mass to 20% by mass as shown in the above [One or more conductive particles of the first conductive particles (MXene particles) and the second conductive particles (MAX particles) included in the conductive member].

Step (a23)

The mixture for forming a conductive member is molded and dried to obtain a conductive member. The mixture can be molded into a molded product in the shape of an electrode or wiring before drying, but the molding method is not particularly limited. For example, the mixture may be applied to an object to be applied such as a substrate. The coating method is not limited, and examples thereof include a method of performing spray coating using a nozzle such as a one-fluid nozzle, a two-fluid nozzle, or an air brush, and a coating method by slit coating using a table coater, a comma coater, or a bar coater, screen printing, metal mask printing, spin coating, dip coating, dropping, or the like. The object to be applied may be appropriately employed as a printed circuit board, a metal substrate, a resin substrate, a laminated electronic component, a metal pin, a metal wire, or the like depending on the application.

Next, drying is performed. The drying condition depends on the shape and size of the molded mixture, but for example, the drying is performed in a range of 60° C. to 200° C. for 10 minutes to 120 minutes.

The application and drying may be repeated a plurality of times as necessary until a film having a desired thickness is obtained.

### Step (b)

The first conductive member and the second conductive member are solder bonded.

### [Solder Material]

The solder metal contained in the solder material is as described above. The solder metal can be, for example, in a powder form. The solder material may include a flux together with a solder metal. Examples of the flux include rosin, a solvent, an activator, and a thickener.

Examples of the rosin include a naturally derived rosin and a modified rosin. Examples of the modified rosin include a rosin obtained by reducing a naturally derived rosin (reduced rosin), a polymerized rosin (polymerization rosin), a disproportionated rosin (disproportionation rosin), and a rosin derivative obtained by introducing a substituent or the like into a naturally derived rosin. The rosin may contain one of the rosin and the rosin derivative described above alone, or may contain two or more in combination.

Examples of the activator include amine halogen salts (For example, the amine is cyclohexylamine, and the halogen is bromine.), for example, amino acids such as glutamic acid, for example, organic acids such as adipic acid, and the like.

Examples of the thickener include those having solubility in organic solvents such as high molecular weight polyethylene glycol, polypropylene glycol, soluble in organic solvents such as ethyl cellulose, hardened castor oil, oils and fats such as coconut oil, waxes of higher alcohols and higher fatty acids, saturated higher fatty acids or alcohols, esters of polyhydric alcohols and higher fatty acids, amides or bisamides of higher fatty acids, carnauba wax, acacia gum, tragacanth gum, guar gum, locust bean gum, arabinogalactone, karaya gum, iris moss, gelatin, sodium alginate, natural or semi-synthetic gums such as propylene glycol alginate, synthetic resins such as low molecular weight phenol formaldehyde resins, low molecular weight polyethylene wax.

When, for example, a solder paste is used as the solder material, the solder material may contain a solvent. Examples of the solvent include glycols such as ethylene glycol, propylene glycol, diethylene glycol, and dipropylene glycol, mono- or diethers with lower alcohols thereof, or mono- or diesters, cyclic ethers, particularly crown ethers, glycerin, pentaerythritol, trimethylolpropane, and esters thereof.

### [Solder Bonding Method]

In the present embodiment, a specific solder bonding method is not particularly limited. Examples of the first conductive member and the second conductive member include a method in which soldering is performed by bringing an electronic circuit board and an electronic component into contact with a solder material melted using, for example, a soldering iron, and a method in which an electronic component is disposed on a printed wiring board on which a solder paste or the like obtained by mixing a solder alloy powder and a flux is printed, and the solder paste or the like is melted in a reflow furnace and solder bonded.

### Embodiment 3: Conductive Member for Solder Bonding

Hereinafter, a conductive member for solder bonding according to an embodiment of the present disclosure is described in detail, but the present disclosure is not limited to such an embodiment.

The conductive member for solder bonding of the present embodiment includes: a conductive member for solder bonding, which is a conductive member that is brought into contact with a solder material by solder bonding, the conductive member including:
a metal;
one or more conductive particles of
(i) first conductive particles being particles of a layered material including one or more layers, the layer including a layer body represented by the following formula:

MₘXₙ
where, M is at least one Group 3, 4, 5, 6, or 7 metal,
X is a carbon atom, a nitrogen atom, or a combination thereof,
n is not less than 1 and not more than 4, and
m is greater than n and 5 or less; and
a modification or termination T (T is at least one selected from the group consisting of a hydroxyl group, a fluorine atom, a chlorine atom, an oxygen atom, and a hydrogen atom.) present on a surface of the layer body; and
(ii) second conductive particles represented by the following formula:

MₘAXₙ
where, M is at least one Group 3, 4, 5, 6, or 7 metal,
X is a carbon atom, a nitrogen atom, or a combination thereof,
A is at least one group 12, 13, 14, 15, or 16 element,
n is not less than 1 and not more than 4, and
m is greater than n and 5 or less.

The conductive member for solder bonding may further include a resin. Details of the resin are as described above in [Resin included in solder-bonded part].

The details of the metal included in conductive member for solder bonding are as described above in [Metal included in conductive member].

In the conductive member for solder bonding of the present embodiment, a solder material including tin may be used for solder bonding. With the conductive member for solder bonding of the present embodiment, dissolution of metallization during soldering can be prevented even when the conductive member is brought into contact with a solder material including tin in solder bonding.

Examples of the conductive member for solder bonding include an electrode or a wiring used for solder bonding. Examples of the “electrode” include an internal electrode, an external electrode, a pad electrode, a wiring electrode, a ground (reference potential) electrode, and a shield pattern in an electronic component or a circuit board, which may cause the dissolution of metallization during soldering. Examples of the “wiring” include a signal line forming a circuit pattern, a coil pattern, and an interlayer connection conductor (via conductor).

### Embodiment 4: Structure for Solder Bonding

The structure for solder bonding of the present embodiment includes the conductive member for solder bonding and a solder material in contact with the conductive member for solder bonding. Details of the conductive member for solder bonding and the solder material are as described above. The conductive member for solder bonding and the solder material have a form in which, for example, at least a part of a surface of the conductive member for solder bonding is covered with the solder material.

### EXAMPLES

### Example 1

In Example 1, a conductive member sample was produced by firing, and MXene powder in Example 1-1 below and MAX particles in Example 1-2 below were used for formation of a conductive member sample.

### Example 1-1

### (1) MAX Particles Preparation

TiC powder, Ti powder, and Al powder (all manufactured by Kojundo Chemical Laboratory Co., Ltd.) were placed in a ball mill containing zirconia balls at a molar ratio of 2:1:1 and mixed for 24 hours. The obtained mixed powder was fired in an Ar atmosphere at 1350° C. for 2 hours. The fired body (block-shaped MAX phase) thus obtained was pulverized to a maximum dimension of 40 μm or less by an end mill. As a result, Ti₃AlC₂ particles were obtained as MAX particles.

### (2) Preparation of MXene Clay and MXene Powder

One g of the Ti₃AlC₂ particles (powder) prepared by the above method was weighed, added to 10 mL of 9 mol/L hydrochloric acid together with 1 g of LiF, and stirred with a stirrer at 35° C. for 24 hours to obtain a solid-liquid mixture (suspension) including a solid component derived from the Ti₃AlC₂ powder. The operation of washing with pure water and separating and removing the supernatant by decantation using a centrifuge (the remaining precipitate excluding the supernatant is washed again) was repeated about 10 times to obtain a clay-like substance (clay) as a precipitate. As a result, a Ti₃C₂Tx—water dispersion clay was obtained as a MXene clay. The Ti₃C₂Tx—water dispersion clay was freeze-dried and pulverized using a mill manufactured by IKA Works, Inc. to obtain a MXene powder.

### (3) Formation of Conductive Member

The MXene powder and the Ag powder (size: 1 μm) were mixed so as to be 14.8% by mass and 85.2% by mass, respectively. The prepared powder was placed in a poly container, and then a plurality of ZrO₂ balls having a diameter of 5 mm were added thereto and mixed in a pot rack. The mixing conditions were 60 rpm and 24 hours. Thereafter, ZrO₂ balls were removed to obtain a mixed powder. Next, the mixed powder was placed in a graphite die of a SPS (Spark Plasma Sintering) apparatus, and molded by pressing and heating to obtain a disk-shaped conductive member sample having a diameter of 10.4 mm and a thickness of 2 mm to 3 mm as a molded product. The conditions for the pressurization and heating were as follows: temperature raising rate: 100° C./min, TOP temperature: 750° C., keeping time: 15 min, Ar atmosphere, and pressurization:maximum 40 MPa.

### Example 1-2

A conductive member sample was obtained in the same manner as in Example 1-1 (3) except that the MAX particles obtained in the same manner as in Example 1 (1) were used instead of the MXene powder.

### Comparative Example 1

A conductive member sample was obtained in the same manner as in Example 1-1 (3) except that the MAX particles or the MXene powder was not added.

### [Test of Dissolution of Metallization During Soldering]

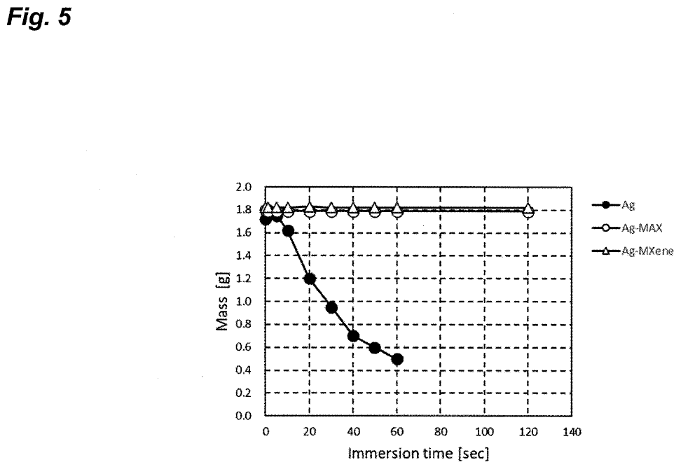

The room temperature conductive member samples obtained in Example 1-1, Example 1-2, and Comparative Example 1 were put into a solder bath (SAC305 composition) heated to 350° C. and melted, and immersed for 120 seconds. In the immersion, the mass was measured for each elapsed time of immersion. In the measurement, one conductive member sample was immersed for a predetermined time and then taken out to measure the mass, immersed again, and taken out after a lapse of a predetermined time and measure the mass repeatedly. The results are shown in FIG. 5 as a graph showing the relationship between the immersion time and the mass of the conductive member sample. In FIG. 5, Ag-MXene and Ag-MAX appear to have unchanged weight, but after being pulled up from the solder bath, an intermetallic compound (alloy layer) with the solder had a thickness of several μm, and the mass increased at a level that cannot be detected by the above measurement.

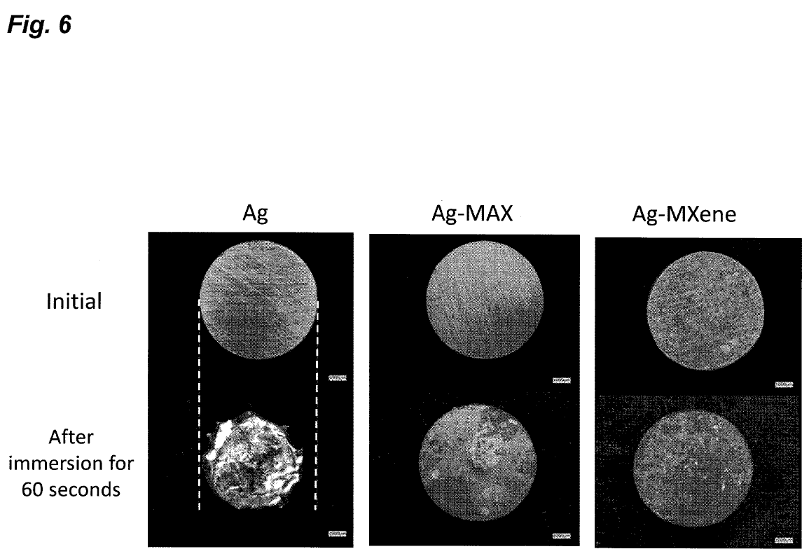

In addition, appearance observation was performed before immersion (initial) and after immersion for 60 seconds. As a result, a microphotograph is shown in FIG. 6. In FIG. 6, microphotographs of “Ag” of Comparative Example 1, “Ag-MAX” of Example 1-2, and “Ag-MXene” of Example 1-1 are shown.

From the photograph of FIG. 6, it can be seen that the conductive member sample formed of only silver as Comparative Example became smaller after immersion for 60 seconds, and dissolution of metallization during soldering occurred. On the other hand, the silver-based conductive member sample including MAX or MXene had no size change and no dissolution of metallization during soldering.

From the graph of FIG. 5, it can be seen that the mass of the conductive member sample formed of only silver as Comparative Example decreased, and also from this graph, dissolution of metallization during soldering occurred as the result of the appearance observation described above. On the other hand, the mass of the conductive member sample including MAX or MXene was not substantially changed, and dissolution of metallization during soldering did not occur as a result of the appearance observation described above.

As shown in the graph of FIG. 5 and the photograph of FIG. 6, dissolution of metallization during soldering did not occur in the conductive member sample including MAX or MXene. This is presumed to be because the presence of MAX or MXene together with silver constituting the conductive member suppressed excessive diffusion of silver to the tin side. In addition, since MAX and MXene have high conductivity, there is no problem that the conductor resistance of the conductive member increases. Further, in the production of the conductive member, only MAX or MXene is mixed with the conventional metal powder for forming the conductive member, or only the mixture is further formed into a paste, and a chemical solution such as an acid or an alkali is not used. Therefore, problems such as a decrease in adhesion strength of the conductor to the substrate and an increase in cost due to addition of a plating process do not occur. In the present Example, a conductive member sample was obtained by a method of producing by sintering, but the present disclosure is not limited thereto, and for example, it is also conceivable to obtain a conductive member sample by kneading an Ag paste, a resin, and MXene powder or MAX particles obtained in the same manner as in Examples 1-1 (1) and (2), printing the mixture on a base material, and drying the mixture. As described above, among the particles of a layered material including one or more layers, one or more conductive particles of the conductive particles (MXene particles) and the second conductive particles (MAX particles) are useful for the production of the conductive member and the production of the bonded structure, and the bonded structure in which the conductive particles are included in the conductive member can exhibit high conductivity without causing dissolution of metallization during soldering.

The bonded structure of the present disclosure may be utilized for any suitable application, and may be particularly preferably used for electrodes in electronic components, for example.

The disclosure herein may include the following aspects.
<1> A bonded structure that includes: a first conductive member; a second conductive member; and a solder-bonded part that bonds the first conductive member and the second conductive member, wherein at least one of the first conductive member and the second conductive member includes:
a metal; and
one or more conductive particles of
(i) first conductive particles being particles including one or more layers, the one or more layers including a layer body represented by the following formula:

MₘXₙ
where a modification or termination T (T is at least one of a hydroxyl group, a fluorine atom, a chlorine atom, an oxygen atom, and a hydrogen atom) is present on a surface of the layer body; and
(ii) second conductive particles represented by the following formula:

MₘAXₙ
where, M is at least one Group 3, 4, 5, 6, or 7 metal,
X is a carbon atom, a nitrogen atom, or a combination thereof,
A is at least one group 12, 13, 14, 15, or 16 element,
n is not less than 1 and not more than 4, and
m is greater than n and 5 or less.
<2> The bonded structure according to <1>, wherein the metal is at least one of silver, copper, gold, nickel, zinc, tin, platinum, and palladium.
<3> The bonded structure according to <1> or <2>, wherein the solder-bonded part contains tin.
<4> The bonded structure according to any one of <1> to <3>, wherein the solder-bonded part includes a resin.
<5> A method for producing a bonded structure, the method including:
(a) preparing a first conductive member and a second conductive member, wherein at least one of the first conductive member and the second conductive member includes:
a metal; and
one or more conductive particles of
(i) first conductive particles being particles including one or more layers, the one or more layers including a layer body represented by the following formula:

MₘXₙ
where a modification or termination T (T is at least one of a hydroxyl group, a fluorine atom, a chlorine atom, an oxygen atom, and a hydrogen atom) is present on a surface of the layer body, and
(ii) second conductive particles represented by the following formula:

MₘAXₙ
where, M is at least one Group 3, 4, 5, 6, or 7 metal,
X is a carbon atom, a nitrogen atom, or a combination thereof,
A is at least one group 12, 13, 14, 15, or 16 element,
n is not less than 1 and not more than 4, and
m is greater than n and 5 or less; and
(b) solder bonding the first conductive member and the second conductive member.
<6> The method for producing a bonded structure according to <5>, wherein at least one of the first conductive member and the second conductive member is prepared by:
(a12) mixing the metal and the one or more conductive particles to obtain a mixture; and
(a13) molding the mixture and firing the mixture at a sinterable temperature to form the at least one of the first conductive member and the second conductive member.
<7> The method for producing a bonded structure according to <6>, wherein the mixture further includes a resin.
<8> The method for producing a bonded structure according to <5>, wherein at least one of the first conductive member and the second conductive member is prepared by:
(a22) mixing the metal, the one or more conductive particles, and a resin to obtain a mixture; and
(a23) molding and drying the mixture to form the at least one of the first conductive member and the second conductive member.
<9> A conductive member for solder bonding, the conductive member comprising:
a metal; and
one or more conductive particles of
(i) first conductive particles being particles including one or more layers, the one or more layers including a layer body represented by the following formula:

MₘXₙ
where a modification or termination T (T is at least one of a hydroxyl group, a fluorine atom, a chlorine atom, an oxygen atom, and a hydrogen atom) is present on a surface of the layer body; and
(ii) second conductive particles represented by the following formula:

MₘAXₙ
where, M is at least one Group 3, 4, 5, 6, or 7 metal,
X is a carbon atom, a nitrogen atom, or a combination thereof,
A is at least one group 12, 13, 14, 15, or 16 element, n is not less than 1 and not more than 4, and
m is greater than n and 5 or less.
<10> The conductive member for solder bonding according to <9>, further including a resin.
<11> The conductive member for solder bonding according to <9> or <10>, wherein the metal is at least one of silver, copper, gold, nickel, zinc, tin, platinum, and palladium.
<12> A structure for solder bonding including: the conductive member for solder bonding according to any one of <9> to <12>; and a solder material to be brought into contact with the conductive member for solder bonding.
<13> The structure for solder bonding according to <12>, wherein the solder material comprises tin.

### REFERENCE SIGNS LIST

1a, 1b Layer body (MₘXₙ layer)
3a, 5a, 3b, 5b Modification or termination T
7a, 7b MXene layer
10a, 10b MXene particles (particles of layered material)
20 Mounting structure
21 Component body
23 Substrate
25 Electrode part
27a, 27b External electrode
29a, 29b Solder-bonded part
31 Solder material
33 Solder-bonded part (alloy layer of metal constituting conductive member and solder alloy, intermetallic compound)
35A Conductive member (without MXene particles/MAX particles)
35B Conductive member (with MXene particles/MAX particles)
36 Metal constituting conductive member
37 One or more of MXene particles and MAX particles
38 Diffusion of solder metal
39 Diffusion of metal constituting conductive member

1. A bonded structure comprising:
a first conductive member;
a second conductive member; and
a solder-bonded part bonding the first conductive member and the second conductive member, wherein
at least one of the first conductive member and the second conductive member includes a metal and particles including one or more layers.

2. The bonded structure according to claim 1, wherein the particles including one or more layers are one or more of
(i) first conductive particles being including one or more layers, the one or more layers including a layer body represented by: MₘXₙ where a modification or termination T is present on a surface of the layer body, wherein T is at least one of a hydroxyl group, a fluorine atom, a chlorine atom, an oxygen atom, and a hydrogen atom, and
(ii) second conductive particles represented by: MₘAXₙ
where, M is at least one Group 3, 4, 5, 6, or 7 metal,
X is a carbon atom, a nitrogen atom, or a combination thereof,
A is at least one group 12, 13, 14, 15, or 16 element,
n is not less than 1 and not more than 4, and
m is greater than n and 5 or less.

3. The bonded structure according to claim 1, wherein the metal is at least one of silver, copper, gold, nickel, zinc, tin, platinum, and palladium.

4. The bonded structure according to claim 1, wherein the solder-bonded part contains tin.

5. The bonded structure according to claim 1, wherein the solder-bonded part comprises a resin.

6. The bonded structure according to claim 1, wherein the particles including one or more layers are one or more of graphene and graphene oxide.

7. The bonded structure according to claim 1, wherein both the first conductive member and the second conductive member are resin-free conductive members.

8. The bonded structure according to claim 1, wherein at least one of the first conductive member and the second conductive member contains a sintered product of the metal and the particles including one or more layers.

9. A method for producing a bonded structure, the method comprising:
(a) preparing a first conductive member and a second conductive member, wherein at least one of the first conductive member and the second conductive member comprises:
a metal; and
one or more conductive particles of:
(i) first conductive particles including one or more layers, the one or more layers including a layer body represented by: MₘXₙ where, a modification or termination T is present on a surface of the layer body, wherein T is at least one of a hydroxyl group, a fluorine atom, a chlorine atom, an oxygen atom, and a hydrogen atom, and
(ii) second conductive particles represented by: MₘAXₙ
where, M is at least one Group 3, 4, 5, 6, or 7 metal,
X is a carbon atom, a nitrogen atom, or a combination thereof,
A is at least one group 12, 13, 14, 15, or 16 element,
n is not less than 1 and not more than 4, and
m is greater than n and 5 or less; and
(b) solder bonding the first conductive member and the second conductive member.

10. The method for producing a bonded structure according to claim 9, wherein at least one of the first conductive member and the second conductive member is prepared by:
(a12) mixing the metal and the one or more conductive particles to obtain a mixture; and
(a13) molding the mixture and firing the mixture at a sinterable temperature to form the at least one of the first conductive member and the second conductive member.

11. The method for producing a bonded structure according to claim 10, wherein the mixture further comprises a resin.

12. The method for producing a bonded structure according to claim 9, wherein at least one of the first conductive member and the second conductive member is prepared by:
(a22) mixing the metal, the one or more conductive particles, and a resin to obtain a mixture; and
(a23) molding and drying the mixture to form the at least one of the first conductive member and the second conductive member.

13. A conductive member for solder bonding, the conductive member comprising:
a metal; and
one or more conductive particles of
(i) first conductive particles being particles including one or more layers, the one or more layers including a layer body represented by: MₘXₙ where a modification or termination T is present on a surface of the layer body, wherein T is at least one of a hydroxyl group, a fluorine atom, a chlorine atom, an oxygen atom, and a hydrogen atom; and
(ii) second conductive particles represented by: MₘAXₙ
where, M is at least one Group 3, 4, 5, 6, or 7 metal,
X is a carbon atom, a nitrogen atom, or a combination thereof,
A is at least one group 12, 13, 14, 15, or 16 element,
n is not less than 1 and not more than 4, and
m is greater than n and 5 or less.

14. The conductive member for solder bonding according to claim 13, further comprising a resin.

15. The conductive member for solder bonding according to claim 13, wherein the metal is at least one of silver, copper, gold, nickel, zinc, tin, platinum, and palladium.

16. A structure for solder bonding comprising:
the conductive member for solder bonding according to claim 13; and
a solder material to be brought into contact with the conductive member for solder bonding.

17. The structure for solder bonding according to claim 16, wherein the solder material comprises tin.
